(19) United States
(12) Patent Application Publication
(10) Pub. No.: US 2013/0021084 A1
(43) Pub. Date: Jan. 24, 2013

(54) LOW VOLTAGE SENSORS WITH INTEGRATED LEVEL TRANSLATORS

(71) Applicant: Manjunath Sreenivasaiah, Bangalore (IN)

(72) Inventor: Manjunath Sreenivasaiah, Bangalore (IN)

(73) Assignee: HONEYWELL INTERNATIONAL INC., Morristown, NJ (US)

(21) Appl. No.: 13/185,182

(22) Filed: Jul. 18, 2011

(51) Int. Cl. H03L 5/00

(52) U.S. Cl. 327/333

(57) ABSTRACT

This disclosure provides techniques for integrating voltage level translators into sensors to provide compatibility between sensor output and inputs to devices that utilize the sensor outputs. According to these techniques, low voltage sensors may be integrated with voltage level translators into an integrated sensing unit that provides data outputs in both low voltage levels and high voltage levels. The integrated sensing unit may provide a selection pin for the output, which may allow utilizing a low voltage output and/or a high voltage output.

### TECHNICAL FIELD

This disclosure relates to sensor circuits, and more particularly, to voltage level translation in sensor circuits.

### BACKGROUND

Sensors are an integral part of many systems that operate based on a sensed condition or parameter. In such systems, sensor outputs are used as input to other parts and devices of the system. In some examples, sensor outputs may not be compatible with the inputs of the parts and/or devices of the system that operate using the sensor outputs.

### SUMMARY

In general, the disclosure describes techniques for integrating voltage level translators into sensors to provide compatibility between sensor output and inputs to devices that utilize the sensor outputs. According to these techniques, low voltage sensors may be integrate with voltage level translators to provide data outputs in both low voltage levels and high voltage levels. In one example, the integrated sensor and voltage level translator may provide a selection pin for the output, which may allow utilizing a low voltage output and/or a high voltage output.

The techniques of this disclosure provide the ability to support low and high voltage outputs, which may depend on the type of device utilizing the sensor data. Additionally, by integrating the sensor with the voltage level translator, the circuitry area utilized is reduced, and the distance over which low voltage data travels is reduced, thus reducing data loss and degradation.

In one example, the disclosure is directed to a method comprising generating, by an integrated sensing unit, at least one signal indicative of at least one measured property, wherein the sensing unit comprises a sensor and a level translator, and communicating, by the integrated sensing unit, the at least one signal via a selected output node coupled to the sensing unit, wherein the at least one signal comprises a low voltage signal when the selected output node is coupled to the sensor, and a high voltage signal when the selected output node is coupled to the level translator.

In another example, the disclosure is directed to a device comprising an integrated sensing unit configured to generate at least one signal indicative of at least one measured property, wherein the sensing unit comprises a sensor and a level translator, a first output node coupled to the sensor; and a second output node coupled to the level translator, wherein the sensing unit communicates the at least one signal via a selected output node coupled to the sensing unit, wherein the at least one signal comprises a low voltage signal when the first output node is selected, and a high voltage signal when the second output node is selected.

In another example, the disclosure is directed to a device comprising means for generating at least one signal indicative of at least one measured property, wherein the means for sensing comprises means for sensing and means for translating voltage levels, and means for communicating the at least one signal via a selected output node coupled to the sensing unit, wherein the at least one signal comprises a low voltage signal when the selected output node is coupled to the means for sensing, and a high voltage signal when the selected output node is coupled to the means for translating.

The details of one or more implementations are set forth in the accompanying drawings and the description below. Other features, objects, and advantages will be apparent from the description and drawings, and from the claims.

### BRIEF DESCRIPTION OF DRAWINGS

FIG. 1 is a block diagram illustrating an example system that utilizes a voltage level translator.

FIG. 2 is a block diagram illustrating an example system that utilizes an integrated voltage level translator, in accordance with techniques of this disclosure.

FIG. 3A illustrates an example serial peripheral interface (SPI) with integrated sensing unit, according to the techniques of this disclosure.

FIG. 3B illustrates an example low voltage SPI device interfaced to a high voltage device.

FIG. 4A illustrates an example inter-integrated circuit (I2C) with integrated sensing unit, according to the techniques of this disclosure.

FIG. 4B illustrates an example low voltage I2C device interfaced to a high voltage device.

FIG. 4C illustrates an example I2C with integrated sensing unit having a humidity sensor, according to techniques of this disclosure.

FIG. 5 is a flow diagram of an example method for generating sensor signals, in accordance with techniques of this disclosure.

### DETAILED DESCRIPTION

Sensors form an integral part of many automation system, where sensor output may not be compatible with inputs of other parts and devices in the system that may utilize the data from the sensor. For example, using a complementary metal-oxide-semiconductor (CMOS) sensor with digital output at 1.8V may not be compatible with a device operating with transistor-transistor logic (TTL) compatible input and output, e.g., at 5V. In this example, a voltage level translator may be utilized between the sensor and the device to ensure successful data transfer from sensor to device and vice versa.

In general, the disclosure describes techniques for integrating voltage level translators into sensors to provide compatibility between sensor outputs and inputs to devices that utilize the sensor outputs. According to these techniques, low voltage sensors may be integrated with voltage level translators to provide data outputs in both low voltage levels and high voltage levels.

In one example, the integrated sensor and voltage level translator module (hereinafter “integrated sensor module”) may provide a selection pin for the output, which may allow utilizing a low voltage output and/or a high voltage output. In this manner, the integrated sensor module may be compatible with devices that operate using low voltage inputs (e.g., CMOS) and with devices that operate using high voltage inputs (e.g., TTL). In one example, a system that has both types of devices, low and high voltage input devices, may utilize an integrated sensor module, where the low voltage output may provide input to the low voltage devices and the high voltage output may provide input to the high voltage devices utilizing the sensor outputs.

The techniques of this disclosure provide the ability to support low or high voltage outputs, which may depend on the type of device utilizing the sensor data. Additionally, by integrating the sensor with the voltage level translator, the utilized circuitry area is reduced. Typically, when a level translator (e.g., at a minimum an 8-pin small-outline integrated circuit (SOIC) package) is connected to a sensing unit, the level translator can take additional space to be added to an existing board, which the design may or may not easily accommodate. When the level translator is integrated with the sensor on to the same chip, the extra space may be saved as the level translator may be fabricated on to the chip using CMOS fabrication technology, for example, instead of having to add it later to an existing board, as connecting the additional components may require additional space. In systems that include data transfer at high data rates, integrating the sensor with the voltage level translator may reduce the distance over which low voltage data travels, and as a result data loss and degradation are reduced.

In one illustrative example, a system utilizing a sensor may be enhanced for low power and compactness. In this example, a user may wish to replace a circuitry associated with a sensor module working on high voltage to a circuitry operating at low voltage, e.g., a low voltage conditioning circuitry, to reduce power consumption and size of the circuit. For example, a microcontroller may replace, in a system, a processor requiring higher voltage, because a microcontroller can operate using less voltage, thus reducing the supply voltage. When a device or circuitry that utilizes output from a sensor, it may be costly to replace the entire system to accommodate voltage level requirements associated with the replacement circuitry, which may be different from the replaced circuitry. In this example, a translator circuits may be implemented between the sensor module and the replacement circuit. Using the techniques of this disclosure, an integrated sensor module may be utilized in the system, where the integrated sensor module may support both low and high voltage outputs. For example, when a low voltage circuitry is connected to the system to replace a high voltage circuitry, previously connected to the integrated sensor module through a high voltage output of the integrated sensor module, may be connected to the integrated sensor module though its low voltage output. In this manner, replacing a significant part of the system does not alter the design of the rest of the system by requiring adjustments to the design or additional components.

In another illustrative example, a system including a sensing module and other devices and components with low voltage, may have data transferred at high data rates from the sensor to a data acquisition system for further processing. The data acquisition system may be at a significant distance from the sensor (e.g., one meter or more). Transferring data from the low voltage devices of the system may not be desirable, as longer distances of data transfer may add delays and cause degradation to the data. In this example, a translator circuit may be implemented between the sensor module and the data acquisition circuit to increase the voltage level associated with the output data, thus decreasing the likelihood of degradation and/or delays. However, in some cases, it may not be possible to place the translator close enough to the sensor as to significantly minimize the effects of distance on the delay and/or degradation of sensor data. Using the techniques of this disclosure, an integrated sensor module may be utilized in the system, where the integrated sensor module may support both low and high voltage outputs. For example, when the output of the sensor is transferred to a data acquisition system that is at relatively a significant distance apart from the sensor, the integrated sensor module may be connected to the data acquisition system through the high voltage output, thus reducing the likelihood of delays and/or data degradation.

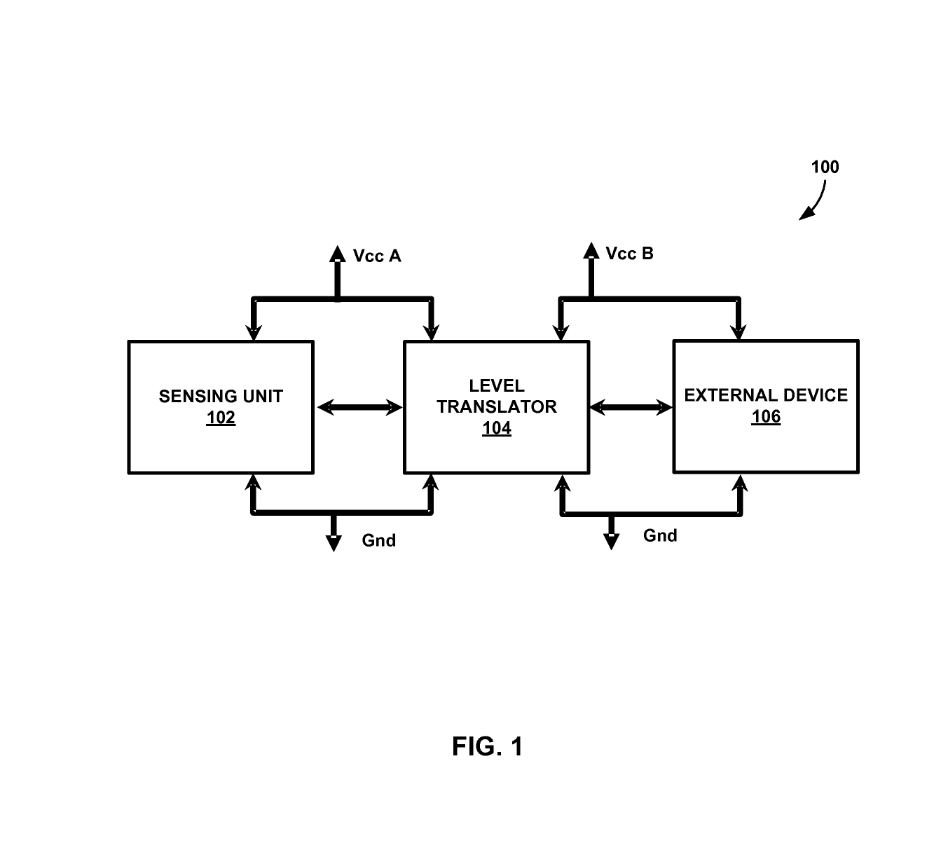

FIG. 1 is a block diagram illustrating an example system 100 that utilizes a voltage level translator. System 100 may be simplified for illustrative purposes. For example, system 100 may be part of a larger sensing and controls system implemented in one or more circuitries. As FIG. 1 shows, system 100 may include sensing unit 102, level translator 104, and external device 106. Sensing unit 102 may be configured to measure one or more values, and generate an output signal (e.g., an analog or digital signal) that indicates the one or more measured values. Typically, sensing unit 102 may be a sensor with low voltage output, i.e., the output signals generated by sensing unit 102 may comprise low voltage signals, such as those generated by low voltage CMOS sensors, e.g., 1.8V-3.3V.

System 100 may include external device 106, which may be a component, device, or an entirely other system that is external to sensing unit 102. External device 106 may utilize in its operation output signals generated by sensing unit 102. In one example, external device 106 may comprise circuitry that operates at high voltage levels, relative to the voltage level of the output signals of sensing unit 102. For example, TTL devices may not be able to read data or input signals at a voltage level lower than a threshold level, e.g., 2.4V. Therefore, the signal levels may not be compatible between sensing unit 102 and external device 106, because external device 106 cannot read data (i.e., output signal) directly output by sensing unit 102. In another example, external device 106 may be a data acquisition system, where data may be transferred at a rate that may cause degradation if not at a high voltage level. Therefore, an additional level translator 104 may be utilized to translate the voltage levels between sensing unit 102 and external device 106 in order to convert the output signal generated by sensing unit 102 to input that external device 106 is capable of reading and utilizing in its operations.

Level translator 104 may be, for example, a bi-directional level translator, which may convert low voltage input (e.g., a signal generated by sensing unit 102) to a high voltage output (e.g., a signal output to external device 106) and may also convert high voltage input (e.g., a signal from external device 106) to a low voltage output (e.g., a signal compatible with sensing unit 102).

As noted above, level translator 104 may comprise an additional component to an existing system when external device 106 is connected to sensing unit 102. Therefore, adding level translator 104 may increase the area dedicated for the circuitry of system 100, which may be limited in some examples. Adding level translator 104 may also increase the complexity of the system and may result in other changes to the system that may increase the cost of the system. Using the techniques of this disclosure the problems associated with system 100 may be overcome as discussed below.

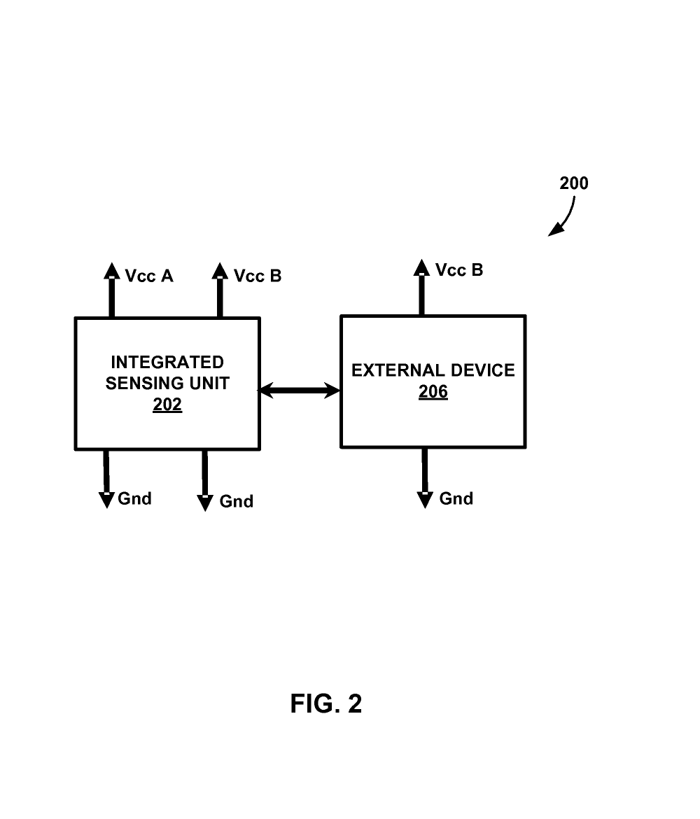

FIG. 2 is a block diagram illustrating an example system 200 that utilizes an integrated voltage level translator, in accordance with techniques of this disclosure. The illustration of system 200 is simplified for demonstrative purposes. For example, system 200 may be part of a larger sensing and controls system implemented in one or more circuitries. As FIG. 2 shows, system 200 may include integrated sensing unit 202 and external device 206.

Integrated sensing unit 202 may include a sensor and a level translator integrated into one component, which may be implemented in system 200. The level translator may be integrated with the sensor such that the sensor part of the integrated sensing unit 202 may be configured to measure one or more values, and generate an output signal (e.g., an analog or digital signal) that indicates the one or more measured values. As noted above, the output signals generated by the sensor may be low voltage signals, such as those generated by low voltage CMOS sensors, e.g., 1.8V.

The level translator part of integrated sensing unit 202 may be, for example, a bi-directional level translator, which may be capable of converting low voltage input a high voltage output and converting high voltage input to a low voltage output. Integrated sensing unit 202 may measure one or more values and provide an output signal at a desired voltage level. In one example, integrated sensing unit 202 may have 2 outputs, where one output may provide a low voltage level output signal and another output may provide a high voltage level output signal. The low voltage level output may correspond to a generated low voltage level signal in response to measured value directly from the sensor part of integrated sensing unit 202. The high voltage level output may correspond to a generated low voltage level signal in response to a measured value from the sensor part then translated to a higher voltage level through the level translator part of integrated sensing unit 202.

System 200 may include external device 206, which may be a component, device, or an entirely other system that is external to integrated sensing unit 202. External device 206 may utilize in its operation output signals generated by integrated sensing unit 202. In one example, external device 206 may comprise circuitry that operates at low voltage levels, similar to those generated by a sensor. In this example, external device 206 may be connected to integrated sensing unit 202 through the output that provides the low voltage level output signal, i.e., directly from the sensor part of integrated sensing unit 202. In another example, external device 206 may comprise circuitry that operates at high voltage levels, relative to the voltage level of the signals generated from the measured values by the sensor part of integrated sensing unit 202. In this example, external device 206 may be connected to integrated sensing unit 202 through the output that provides the high voltage level output signal, i.e., the signal generated by the level translator part of integrated sensing unit 202.

In one example, external device 206 may comprise a low voltage or high voltage device, and may be connected to integrated sensing unit 202 via the output corresponding to the desired voltage level. If external device 206 is replaced with another external device with different voltage level requirements, the architecture of system 200 remains unchanged, as there would be no need to add or remove components. Instead, connections between the external device and integrated sensing unit 202 may be modified to the appropriate output based on the required voltage level.

In one example, integrated sensing unit 202 may be designed as part of an integrated circuit where the sensor and level translator may be used on the integrated circuit. In another example, the level translator may be wire-bonded as a discrete element during fabrication. Other methods of integrating the level translator with the sensor may be utilized such that external devices (e.g., external device 206) may be connected without altering the system design or requiring additional components.

In one example, the system that includes integrated sensing unit 202 may include an application implemented in split plane of low voltage and high voltage. Split planes may be used when a system requires two different voltage levels to be implemented on the same board. For example, a system may require a microcontroller that operates using 1.8V-2.3V supply and a display that operates using 3.3V-5.5V power supply. In this example, integrated sensing unit 202 may be used to feed data to both the microcontroller and the display, where the data supplied to the microcontroller may be provided using the low voltage output and the data supplied to the display may be provided using the high voltage output,

In other examples, integrated sensing unit 202 may be utilized in systems that require data transfers at high data rates, where transferring data at low voltage levels for long distances may cause delays in the data transfer and/or cause degradation. Using integrated sensing unit 202, the voltage level associated with the sensor data may be increased using the integrated level translator, thus reducing likelihood of data degradation. Additionally, by using an integrated sensing unit, the distance the data travels while at a low voltage level may be minimized such that adverse effects of long distance of transfer on data (e.g., delays, degradation) may be greatly reduced.

Using the techniques of this disclosure may allow custom circuit development without causing an increase in cycle time or the time required to produce circuits in a production line. Additionally, cost and complexity of circuitry design associated with production and design of systems that utilize sensors and level translators may be reduced, by reducing the number of associated discrete components. For example, when switching from low voltage level signal to high voltage level signal from a sensor, instead of removing or adding a level translator, a simple pin selection may switch the output signal of the integrated sensing unit from the low voltage level (bypassing the level translator) to the high voltage level (going through the level translator).

While the techniques of this disclosure are described using the example of low voltage sensors, it should be understood that these techniques may be utilized with other low voltage components and devices, e.g., actuators and the like, and modified accordingly. Integrated sensing units, e.g., integrated sensing unit 202, may be utilized in different types of circuits and systems. Some example systems or circuits in which integrated sensing units may be utilized are serial peripheral interface (SPI) and inter-integrated circuit (I2C).

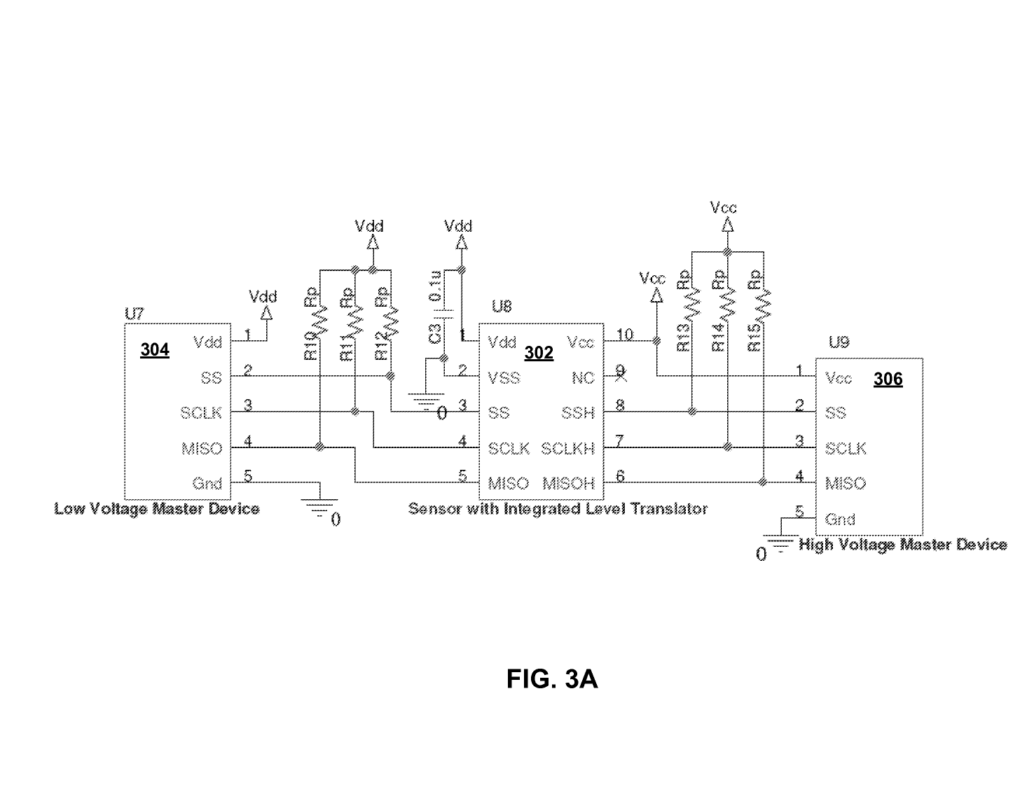

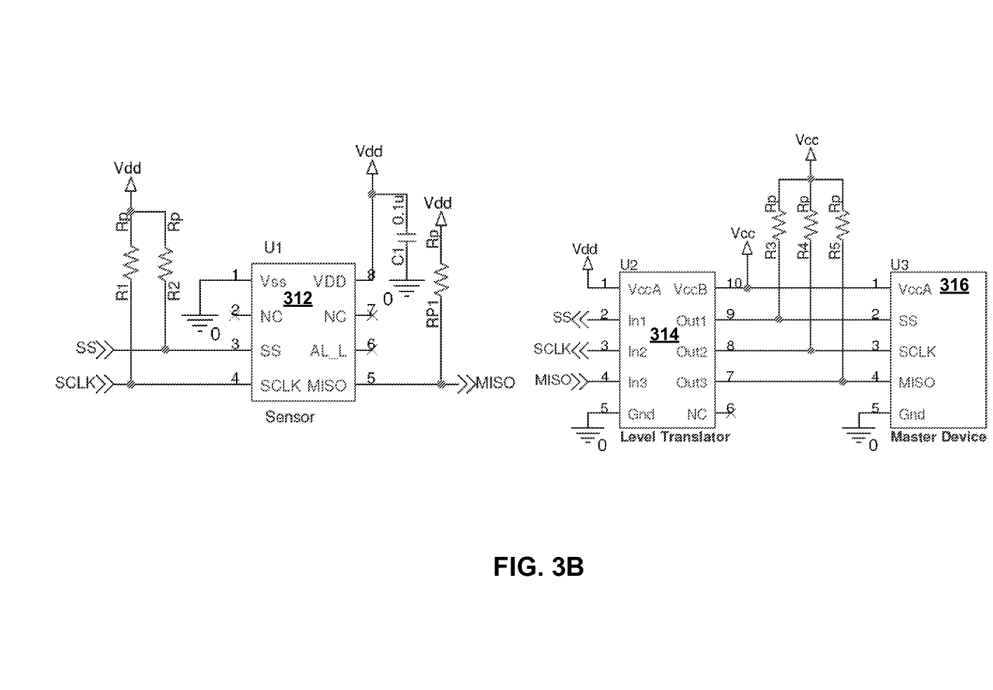

FIG. 3A illustrates an example SPI with integrated sensing unit, according to the techniques of this disclosure. The example of FIG. 3A shows a connection diagram for a SPI output sensor with integrated level translator (or integrated sensing unit) interfaced to both low voltage and high voltage master. The SPI circuit may include integrated sensing unit 302, low voltage device 304, and high voltage device 306. In this example, SS may indicate the slave select line, SCLK the serial clock line, MISO the master in slave out line, SSH the high voltage level SS, SCLKH the high voltage level SCLK, and MISOH the high voltage level MISO. SS and SSH may be used to select the required sensor output, either directly to get low voltage output or through the translator to get high voltage output. SCLK and SCLKH are serial clock lines controlled by the corresponding master device, which is used for serial communication. MISO and MISOH may be used to transfer data between the slave device (e.g., integrated sensing unit 302) and the appropriate master device (e.g., low voltage device 304 or high voltage device 306). Rp may indicate the pullup resistor, where its value may depend on the required current. The required current may be determined using characteristics of the cable, e.g., the capacitance per unit length of the cable, cable length, and the data transfer rate over the cable. For example, higher data rates and a longer cable requires more current and therefore less resistance, and lower data rate and a shorter cable require less current and therefore higher resistance.

In the example of FIG. 3A, integrated sensing unit 302 may be utilized with two devices, low voltage device 304 utilizing low voltage output based on sensor measurement, and high voltage device 306 utilizing high voltage output based on sensor measurements. Integrated sensing unit 302 may provide a low voltage level signal, where the signal generated using sensor measurement may be used directly as input to low voltage device 304. Integrated sensing unit 302 may also provide a high voltage level signal, where the signal generated using sensor measurements may go through the integrated voltage level translator to provide a high voltage level signal to high voltage device 306. In this example, Vdd may indicate the sensor supply voltage and may range between 1.8V to 5.5V, and Vcc may indicate the voltage level associated with the high voltage device (e.g., data acquisition system) and may range between 3.3V and 5.5V.

In the example of SPI systems, each master device (e.g., external devices 304 and 306) may have a slave select pin. When a master device needs data from the slave device (e.g., integrated sensing unit 302), the appropriate SS pin (e.g., SS or SSH) may be pulled low and the slave device starts transmitting data to the requesting master device. Therefore, in this example, multiple master devices connected to a slave device may be individually accessed by selecting the appropriate slave select pin. The signals between the devices may be digital at a specified frequency. SPI may operate at a frequency, which may be determined by the master device controlling the clock of the system.

FIG. 3B illustrates an example low voltage SPI device interfaced to a high voltage device. The example of FIG. 3B shows one method of interfacing a low voltage SPI device to a high voltage device through a level translator. The example system of FIG. 3B may include sensor 312, level translator 314, and master device 316. In this example, the low voltage SPI device, or sensor 312 may be interfaced to the high voltage device or master device 316 through level translator 314. As FIG. 3B illustrates, in this example, when high voltage device 316 is connected to sensor 312, level translator 314 needs to be added to the circuitry, thus adding to the complexity of the circuitry and adding extra components. Other issues associated with the example of FIG. 3B may be an increase in parasitic capacitance and limitations on data transfer rates caused by using cables to connect the difference components, reduction in the distance over which data may be transferred without additional data degradation, and an increase in external dependency on the level translator supplier.

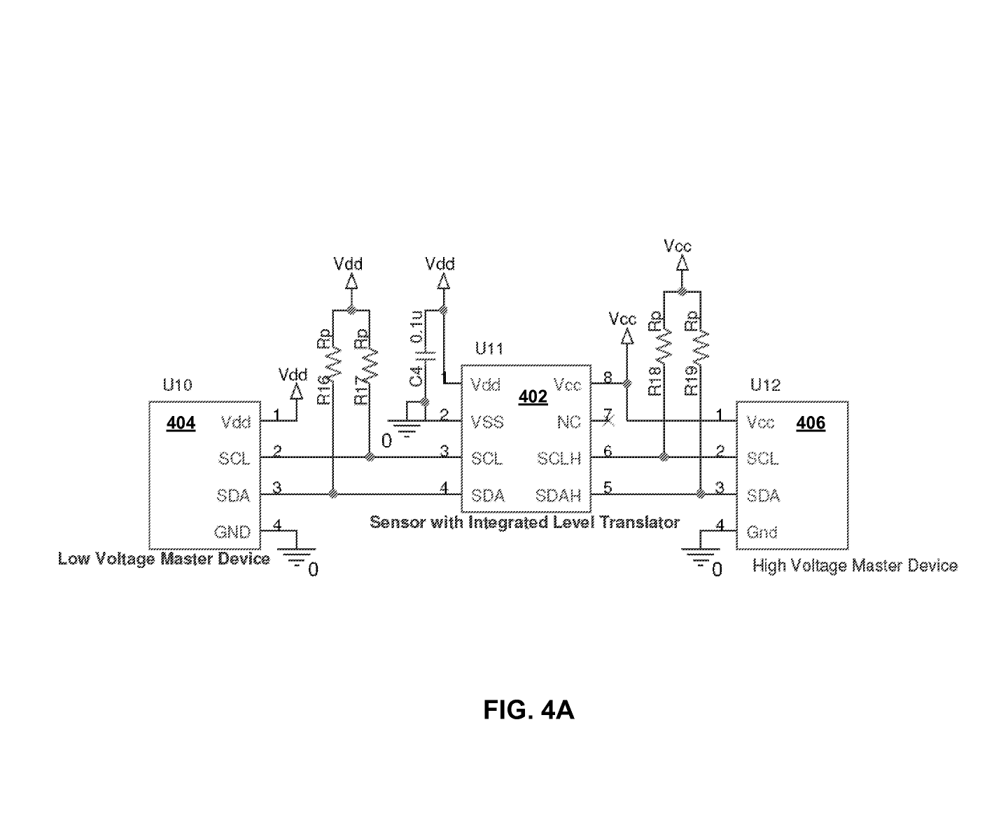

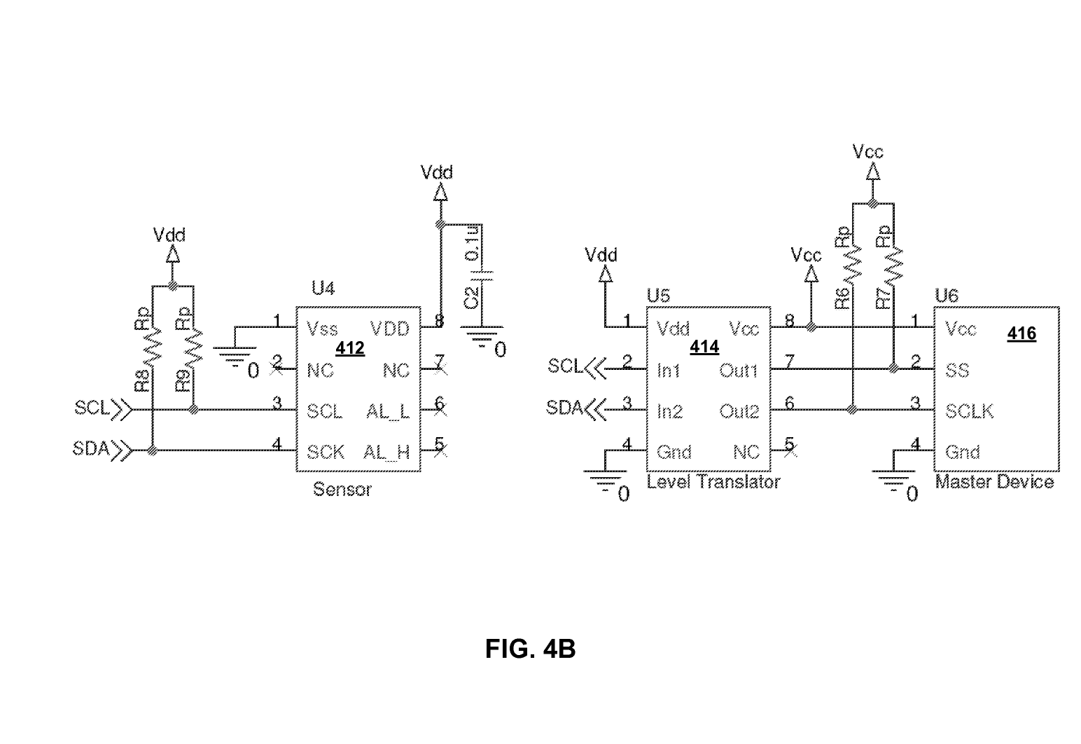

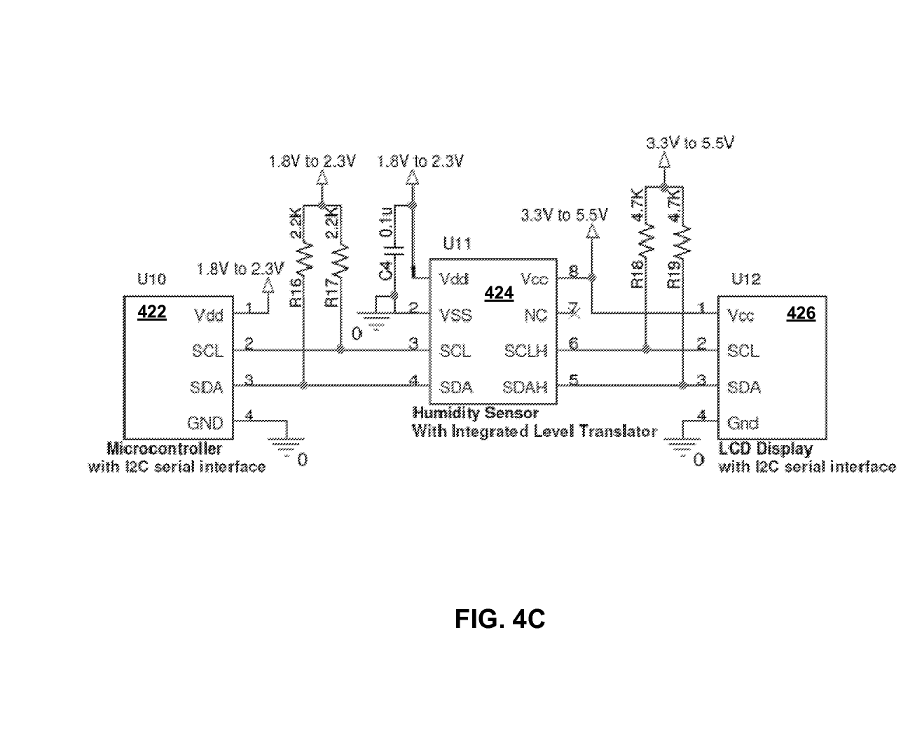

FIG. 4A illustrates an example I2C with integrated sensing unit, according to the techniques of this disclosure. The example of FIG. 4A shows a connection diagram for an I2C output sensor with integrated level translator (or integrated sensing unit) interfaced to both low voltage and high voltage master. The I2C may include integrated sensing unit 402, low voltage device 404, and high voltage device 406. In this example, SCL may indicate the serial clock line, SDA the serial data line, SCLH the high voltage level SCL, and SDAH the high voltage level SDA. SCL and SCLK are serial clock lines controlled by the corresponding master device, which is used for serial communication. SDA and SDAH may be used to select the required sensor output, either directly to get low voltage output or through the translator to get high voltage output, and to transfer data between the slave device (e.g., integrated sensing unit 402) and the appropriate master device (e.g., low voltage device 404 or high voltage device 406).

In the example of I2C systems, each device may have a specific address. The master device (e.g., external devices 404 and 406) may send a signal to the slave device (e.g., integrated sensing unit 402) requesting a measured parameter value (e.g., humidity, temperature, pressure, and the like). The slave device then sends the requested data to the master devices. The devices in an I2C system may interact via I2C protocol. The signals between the devices may be digital at a specified frequency. I2C may operate in 3 different modes: standard mode (100 kpbs), fast mode (400 kpbs), and high speed mode (3.4 mps).

In the example of FIG. 4B, integrated sensing unit 402 may be utilized with two devices, low voltage device 404 utilizing low voltage output based on sensor measurement, and high voltage device 406 utilizing high voltage output based on sensor measurements. Integrated sensing unit 402 may provide a low voltage level signal, where the signal generated using sensor measurement may be used directly as input to low voltage device 404. Integrated sensing unit 402 may also provide a high voltage level signal, where the signal generated using sensor measurements may go through the integrated voltage level translator to provide a high voltage level signal to high voltage device 406. In this example, Vdd may indicate the sensor supply voltage and may range between 1.8V to 5.5V, and Vcc may indicate the voltage level associated with the high voltage device (e.g., data acquisition system) and may range between 3.3V and 5.5V.

FIG. 4B illustrates an example low voltage I2C device interfaced to a high voltage device. The example of FIG. 4B shows one method of interfacing a low voltage I2Cdevice to a high voltage device through a level translator. The example system of FIG. 4B may include sensor 412, level translator 414, and master device 416. In this example, the low voltage I2C device, or sensor 412 may be interfaced to the high voltage device or master device 416 through level translator 414. As FIG. 4B illustrates, in this example, when high voltage device 416 is connected to sensor 412, level translator 414 needs to be added to the circuitry, thus adding to the complexity of the circuitry and adding extra components. Other issues associated with the example of FIG. 4B may be similar to those noted above with FIG. 3B, e.g., an increase in parasitic capacitance and limitations on data transfer rates caused by using cables to connect the difference components, reduction in the distance over which data may be transferred without additional data degradation, and an increase in external dependency on the level translator supplier.

Additionally, using this design, there may be a limited number of devices which may be connection to the bus, as the protocol has a limitation on parasitic capacitance, e.g., 10 pF-100 pF for the pullup resistor, and anything above this bus capacitance limitation may require an additional current source.

FIG. 4C illustrates an example I2C with integrated sensing unit having a humidity sensor, according to techniques of this disclosure. The example of FIG. 4C may be one specific implementation of the system illustrated in FIG. 4A. The example of FIG. 4C shows a connection diagram for an I2C output sensor with integrated level translator (or integrated sensing unit) interfaced to both low voltage and high voltage master. The I2C may include integrated sensing unit 422, low voltage device 424, and high voltage device 426. In this example, integrated sensing unit 422 may include a humidity sensor that measures humidity values. Integrated sensing unit 422 may provide a signal indicative of the measured humidity value through the I2C interface.

Integrated sensing unit 422 may provide humidity data to other parts and/or devices of the system, which may be operating at different voltage levels. For example, integrated sensing unit 422 may provide humidity data to low voltage device 424, e.g., a microcontroller, through a low-voltage output. Integrated sensing unit 422 may also provide humidity data to high voltage device 426, e.g., a display device, through a high-voltage output.

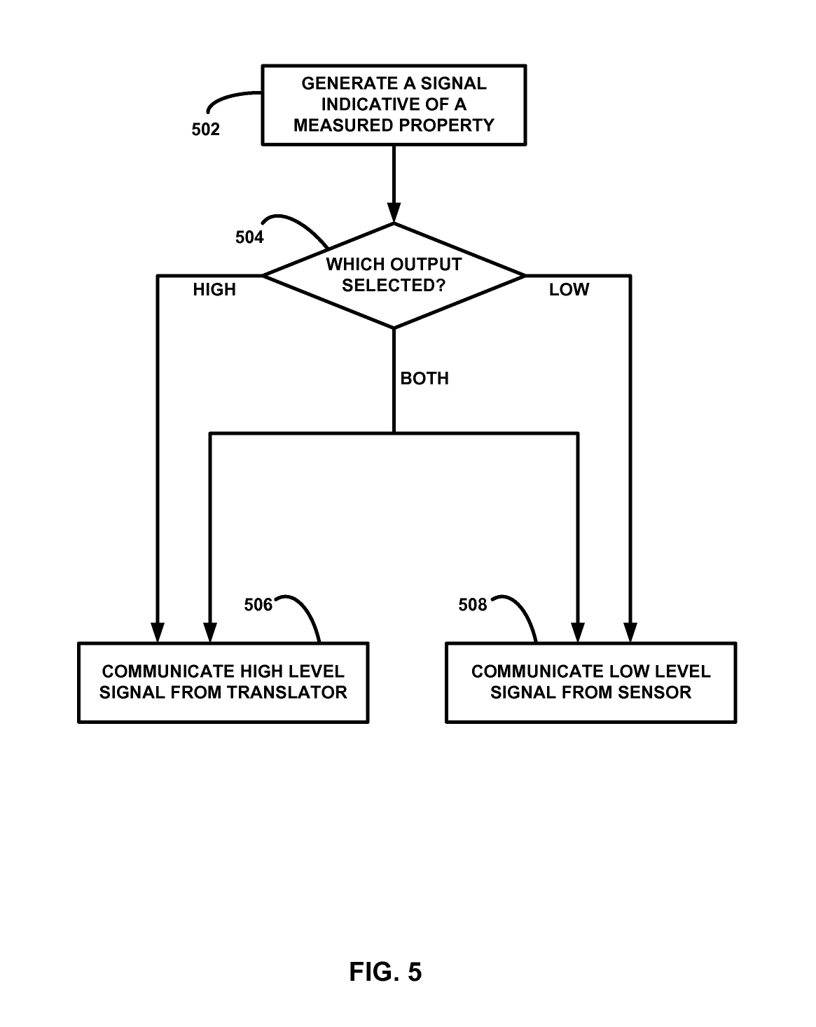

FIG. 5 is a flow diagram of an example method for generating sensor signals, in accordance with techniques of this disclosure. The illustrated example method may be performed by integrated sensing unit 202. The method of FIG. 5 includes the integrated sensing unit generating at least one signal indicative of at least one measured property (502). The integrated sensing unit may include a sensor and a level translator, where the sensor may be a low voltage sensor capable of generating a measured property based on a sensed condition. The level translator may be a bi-directional voltage level translator capable of converting low voltage level signals to high voltage level signals and vice versa.

The integrated sensing unit may include a first output node connected to the sensor and a second output node connected to the level translator. In one example, the integrated sensing unit may include a selector that selects either the first output node or the second output node, or both. The method of FIG. 5 may further include determining whether the first output node, the second output node, or both the first and second nodes are selected (504).

When the first output node is selected, the output of the integrated sensing unit corresponds to the output of the sensor, and is therefore a low voltage output. The first output node may be selected when a low voltage external device is coupled to the integrated sensing unit. When the first output node is selected, the method further comprises communicating a low voltage level signal from the sensor to the external device via the first output node (508).

When the second output node is selected, the output of the integrated sensing unit corresponds to the output of the voltage level translator, and is therefore a high voltage output. The second output node may be selected when a high voltage external device is coupled to the integrated sensing unit. When the second output node is selected, the method further comprises communicating a high voltage level signal from the voltage level translator to the external device via the second output node (506).

When both the first and second nodes are selected, both outputs of the integrated sensing unit are active, therefore, the integrated sensing unit provides a high voltage output corresponding to the output of the voltage level translator, and a low voltage output corresponding to the output of the sensor. When both output nodes are selected, the method further comprises communicating a high voltage level signal from the voltage level translator to the external device via the second output node (506) and a low voltage level signal from the sensor to the external device via the first output node (508).

The techniques described in this disclosure may be implemented, at least in part, in hardware, software, firmware, or any combination thereof. For example, various aspects of the described techniques may be implemented within one or more processors, including one or more microprocessors, digital signal processors (DSPs), application specific integrated circuits (ASICs), field programmable gate arrays (FPGAs), or any other equivalent integrated or discrete logic circuitry, as well as any combinations of such components. The term “processor” or “processing circuitry” may generally refer to any of the foregoing logic circuitry, alone or in combination with other logic circuitry, or any other equivalent circuitry. A control unit including hardware may also perform one or more of the techniques of this disclosure.

Such hardware, software, and firmware may be implemented within the same device or within separate devices to support the various techniques described in this disclosure. In addition, any of the described units, modules or components may be implemented together or separately as discrete but interoperable logic devices. Depiction of different features as modules or units is intended to highlight different functional aspects and does not necessarily imply that such modules or units must be realized by separate hardware, firmware, or software components. Rather, functionality associated with one or more modules or units may be performed by separate hardware, firmware, or software components, or integrated within common or separate hardware, firmware, or software components.

The techniques described in this disclosure may also be embodied or encoded in a computer-readable medium, such as a computer-readable storage medium, containing instructions. Instructions embedded or encoded in a computer-readable medium, including a computer-readable storage medium, may cause one or more programmable processors, or other processors, to implement one or more of the techniques described herein, such as when instructions included or encoded in the computer-readable medium are executed by the one or more processors. Computer readable storage media may include random access memory (RAM), read only memory (ROM), programmable read only memory (PROM), erasable programmable read only memory (EPROM), electronically erasable programmable read only memory (EEPROM), flash memory, a hard disk, a compact disc ROM (CD-ROM), a floppy disk, a cassette, magnetic media, optical media, or other computer readable media. In some examples, an article of manufacture may comprise one or more computer-readable storage media.

In some examples, a computer-readable storage medium may comprise a non-transitory medium. The term “non-transitory” may indicate that the storage medium is not embodied in a carrier wave or a propagated signal. In certain examples, a non-transitory storage medium may store data that can, over time, change (e.g., in RAM or cache).

Various embodiments of the invention have been described. These and other embodiments are within the scope of the following claims.

1. A method comprising:
generating, by an integrated sensing unit, at least one signal indicative of at least one measured property, wherein the sensing unit comprises a sensor and a level translator; and
communicating, by the integrated sensing unit, the at least one signal via a selected output node coupled to the sensing unit,
wherein the at least one signal comprises a low voltage signal when the selected output node is coupled to the sensor, and a high voltage signal when the selected output node is coupled to the level translator.

2. The method of claim 1, wherein the sensor comprises a low voltage sensor.

3. The method of claim 1, wherein the level translator comprises a bi-directional level translator.

4. The method of claim 1, further comprising communicating the at least one signal to an external device coupled to the selected output node.

5. The method of claim 4, wherein the selected output node is coupled to the sensor when the external device comprises a low voltage input device, and the selected output node is coupled to the level translator when the external device comprises a high voltage input device.

6. A device comprising:
an integrated sensing unit configured to generate at least one signal indicative of at least one measured property, wherein the sensing unit comprises a sensor and a level translator;
a first output node coupled to the sensor; and
a second output node coupled to the level translator,
wherein the sensing unit communicates the at least one signal via a selected output node coupled to the sensing unit,
wherein the at least one signal comprises a low voltage signal when the first output node is selected, and a high voltage signal when the second output node is selected.

7. The device of claim 6, wherein the sensor comprises a low voltage sensor.

8. The device of claim 6, wherein the level translator comprises a bi-directional level translator.

9. The device of claim 6, wherein the at least one signal is communicated to an external device coupled to the selected output node.

10. The device of claim 9, wherein the selected output node comprises the first output node when the external device comprises a low voltage input device, and the second output node when the external device comprises a high voltage input device.

11. A device comprising:
means for generating at least one signal indicative of at least one measured property, wherein the means for generating comprises means for sensing and means for translating voltage levels; and
means for communicating the at least one signal via a selected output node coupled to the sensing unit,
wherein the at least one signal comprises a low voltage signal when the selected output node is coupled to the means for sensing, and a high voltage signal when the selected output node is coupled to the means for translating.

12. The device of claim 11, wherein the means for sensing comprises a low voltage sensor.

13. The device of claim 11, wherein the means for translating comprises a bi-directional level translator.

14. The device of claim 11, further comprising means for communicating the at least one signal to an external device coupled to the selected output node.

15. The device of claim 14, wherein the selected output node is coupled to the means for sensing when the external device comprises a low voltage input device, and to the means for translating when the external device comprises a high voltage input device.
